(19) United States
(12) Patent Application Publication
(10) Pub. No.: US 2010/0277357 A1
(43) Pub. Date: Nov. 4, 2010

(54) ANALOG-TO-DIGITAL CONVERTER

(76) Inventors: Young-Joon Ko, Daejon (KR); Mi-Kyung Oh, Gyeongbuk (KR); Joo-Ho Park, Daejon (KR); Jae-Young Kim, Daejon (KR); Kwang-Roh Park, Daejon (KR); Suk-Ki Kim, Seoul (KR); Yun-Jeong Kim, Seoul (KR)

Correspondence Address: STAAS & HALSEY LLP, SUITE 700, 1201 NEW YORK AVENUE, N.W., WASHINGTON, DC, 20005, US

(21) Appl. No.: 12/747,666

(22) PCT Filed: Apr. 18, 2008
(86) PCT No.: PCT/KR08/02209

§ 371 Date: Jun. 11, 2010

(30) Foreign Application Priority Data
Dec. 12, 2007 (KR) 10-2007-0128820

(51) Int. Cl. H03M 1/12

(52) U.S. Cl. 341/155

(57) ABSTRACT

Provided is an analog-to-digital converter. The analog-to-digital converter includes a resistor string for generating a plurality of reference voltages; a plurality of differential difference amplifiers for detecting zero-crossing points according to interpolation by using the plurality of reference voltages and input signals; and a plurality of comparators for receiving outputs of the plurality of differential difference amplifiers, detecting zero-crossing points according to 4X interpolation, and generating a digital code corresponding to the input signals.

### TECHNICAL FIELD

The present invention relates to an analog-to-digital converter; and, more particularly, to an analog-to-digital converter having an interpolation circuit capable of reducing power consumption and circuit area in spite of increase of resolution.

This work was supported by the Information Technology (IT) research and development program of the Korean Ministry of Information and Communication (MIC) and the Korean Institute for Information Technology Advancement (IITA) [2006-S-070-02, “Development of Cognitive Wireless Home Networking System”].

### BACKGROUND ART

In recent high-density integrated circuits (ICs) such as very-large-scale integration (VLSI) ICs or ultra-large-scale integration (ULSI) ICs, there is an increasing demand on technologies for implementing the on-chip of analog-to-digital interface. In particular, among analog-to-digital interface technologies, a high-speed analog-to-digital converter (ADC) with low power and high resolution has been widely used in various application fields. ADCs can be designed in various structures. A pipeline ADC can have a data conversion rate of several hundred MHz and a 10-bit resolution. A flash ADC can have a 6-bit resolution and a data conversion rate of more than 1 GS/s.

Different ADCs are used in different technical application fields. For example, oversampling ADCs using sigma/delta modulator are widely used in voice processing fields requiring a high resolution and a low data conversion rate. Meanwhile, pipeline ADCs are widely used in high-speed signal processing fields including video signal processing. Especially, many attempts have been made to optimize power consumption for resolution required when ADCs are used in mobile communication fields. Also, flash ADCs are widely used in application fields requiring a high resolution and a high conversion rate, such as a read-channel system of DVD, a receiver for high-speed serial data communication including optical communication, a digital communication system, and a display controller of HDTV.

A conventional high-speed CMOS ADC has generally used a full-flash scheme. However, as the resolution increases, the number of comparators also increases. Hence, a total chip area increases and power consumption increases. To solve these disadvantages, a folding and interpolating ADC using a folding and interpolation technology was proposed. An advantage of the interpolation technology is that the number of comparators is reduced compared with the full-flash ADC. However, since the number of latches is still equal to that in the full-flash ADC, the folding technology is also applied to the ADC in order to reduce the number of the latches. Consequently, the total chip area as well as the number of the latches can be reduced.

FIG. 1 is a block diagram of a flash ADC using a conventional interpolation technology. The ADC having a 6-bit resolution will be exemplarily described.

In the ADC of FIG. 1, a 4X interpolation technology is designed using two-stage circuits. The ADC includes 17 reference voltage resistors (not shown), 17 differential difference amplifiers (DDAs), 31 interpolation amplifiers I/A1 to I/A31, and 63 comparators 1 to 63. That is, the ADC implements the 4X interpolation technology through two times 2X interpolation technologies. The 17 reference voltage resistors (not shown) are provided between the respective reference voltages VREF1 to VREF17 input to the respective differential difference amplifiers. The interpolation amplifiers I/A1 to I/A31 use the interpolation technology to calculate zero-crossing points with respect to the respective outputs of the 17 differential difference amplifiers DDA1 to DDA17. In addition, each of the comparators 1 to 63 includes a preamplifier and a latch in order to reduce kickback noise. Consequently, 63 preamplifiers and 63 latches are included in the 63 comparators 1 to 63.

If the interpolation technology is not used, the ADC must include 63 reference voltages, 63 differential difference amplifiers, and 63 comparators in order to obtain a 6-bit digital code, where the bit number of the digital code represents a resolution. In addition, when the 2X interpolation technology is used instead of the 4X interpolation technology, the ADC needs 31 reference voltages, differential difference amplifiers, 63 comparators each including a preamplifier and a latch, and a resistor or amplifier for interpolation between the differential difference amplifiers and the comparators in order to obtain a 6-bit digital code.

As described above, the application of the interpolation technology to the ADC can reduce the number of the differential difference amplifiers, the number of the reference voltages applied to the differential difference amplifiers, and the number of the reference voltage resistors for generating the respective reference voltages, thereby reducing a total chip area. However, when the ADC is designed such that the conventional 4X interpolation technology is implemented by two times the 2X interpolation technology, 31 interpolation amplifiers I/A1 to I/A31 are included in the comparator. Thus, there is a limitation in reducing the chip area and power consumption. In other words, when the interpolation technology is not used, the hardware complexity and power consumption are increased by 2N with respect to the bit number N representing the resolution. On the contrary, the hardware complexity and power consumption can be reduced by reducing the number of the differential difference amplifiers and the reference voltages by ½ through the interpolation technology used for reduction of the power consumption.

When the interpolation technology is applied to the flash ADC, the ADC having an N-bit resolution can be implemented using (2N/2)−1 reference voltage resistors and differential difference amplifiers, which function to amplify the reference voltages and analog signals, and 2N−1 comparators. As illustrated in FIG. 1, in order to further reduce the complexity, the interpolation circuit is configured with two stages. The ADC is implemented using (2N/4)+1 reference voltage resistors and differential difference amplifiers, (2N/2)−1 interpolation amplifiers, and 2N−1 comparators. An entire characteristic of the ADC can be improved due to input impedance reduced by the two-stage interpolation technology. However, the flash ADC still requires low power characteristic and more efficient low power circuit design technology.

### DISCLOSURE

### Technical Problem

An embodiment of the present invention is directed to providing a flash ADC that can reduce circuit area and power consumption by reducing interpolation stages in implementation of an interpolation technology required in an ADC design.

Other objects and advantages of the present invention can be understood by the following description, and become apparent with reference to the embodiments of the present invention. Also, it is obvious to those skilled in the art of the present invention that the objects and advantages of the present invention can be realized by the means as claimed and combinations thereof.

### Technical Solution

In accordance with an aspect of the present invention, there is provided an analog-to-digital converter (ADC), including: a resistor string for generating a plurality of reference voltages; a plurality of differential difference amplifiers for detecting zero-crossing points according to interpolation by using the plurality of reference voltages and input signals; and a plurality of comparators for receiving outputs of the plurality of differential difference amplifiers, detecting zero-crossing points according to 4X interpolation, and generating a digital code corresponding to the input signals.

In accordance with another embodiment of the present invention, there is provided an analog-to-digital converter (ADC), including: (2N/4)+1 reference voltage resistors (where N is a natural number) for generating a plurality of reference voltages; (2N/4)+1 differential difference amplifiers for detecting zero-crossing points according to interpolation by using the plurality of reference voltages generated from the (2N/4)+1 reference voltage resistors and input signals; and 2N−1 comparators for detecting zero-crossing points according to 4X interpolation through outputs of the (2N/4)+1 differential difference amplifiers, whereby the analog-to-digital converter has a resolution corresponding to an N-bit digital signal.

In the design of the flash ADC, the interpolation technology is required to reduce power consumption and circuit area that increase as the resolution increases. In accordance with the embodiments of the present invention, in the design of the ADC using the interpolation technology, a comparator for comparing the reference voltage with the input signal also performs the interpolation function, thereby reducing the interpolation stages and the operation circuits. The reduction of the interpolation stages and the operation circuits reduces the number of the reference voltage resistor strings and the number of the preamplifiers used in the flash ADC, thereby reducing the power consumption and circuit area. Specifically, the design of the comparator used in the flash ADC is modified such that the comparator can perform the interpolation operation. Thus, this can reduce the interpolation stages required in the design of the ADC, the number of the resistor strings for generating the reference voltages, and the number of the preamplifiers for generating difference between the input voltages and the reference voltages. Consequently, the flash ADC using the 4X interpolation technology can reduce the power consumption and circuit area.

### ADVANTAGEOUS EFFECTS

In accordance with the embodiments of the present invention, the ADC using the interpolation technology can provide the reduced chip area and power consumption and the increased operating speed by removing the causes of increasing the chip area and power consumption through the design modification of the comparator without additional circuits for interpolation.

Specifically, the 4X interpolation circuit is proposed for reducing the circuit area and power consumption caused by an interpolation technology used in the flash ADC, thereby reducing multi-stage circuits that have been used for the conventional interpolation operation.

### BRIEF DESCRIPTION OF THE DRAWINGS

FIG. 1 is a block diagram of a flash ADC using a conventional interpolation technology.

FIG. 2 is a block diagram of a flash ADC using an interpolation technology in accordance with an embodiment of the present invention.

FIG. 3 is a conceptual diagram for explaining zero-crossing points using the interpolation technology in accordance with an embodiment of the present invention.

FIG. 4 is a circuit diagram of a comparator for the 4X interpolation technology in the ADC of FIG. 2 in accordance with an embodiment of the present invention.

FIG. 5 is a waveform diagram for explaining the simulation result of the operation of the comparator illustrated in FIG. 4.

FIG. 6 is a circuit diagram of a comparator for the 4X interpolation technology in the ADC of FIG. 2 in accordance with another embodiment of the present invention.

### BEST MODE FOR THE INVENTION

The advantages, features and aspects of the invention will become apparent from the following description of the embodiments with reference to the accompanying drawings, which is set forth hereinafter. Therefore, those skilled in the field of this art of the present invention can embody the technological concept and scope of the invention easily. In addition, if it is considered that detailed description on a related art may obscure the points of the present invention, the detailed description will not be provided herein. The preferred embodiments of the present invention will be described in detail hereinafter with reference to the attached drawings.

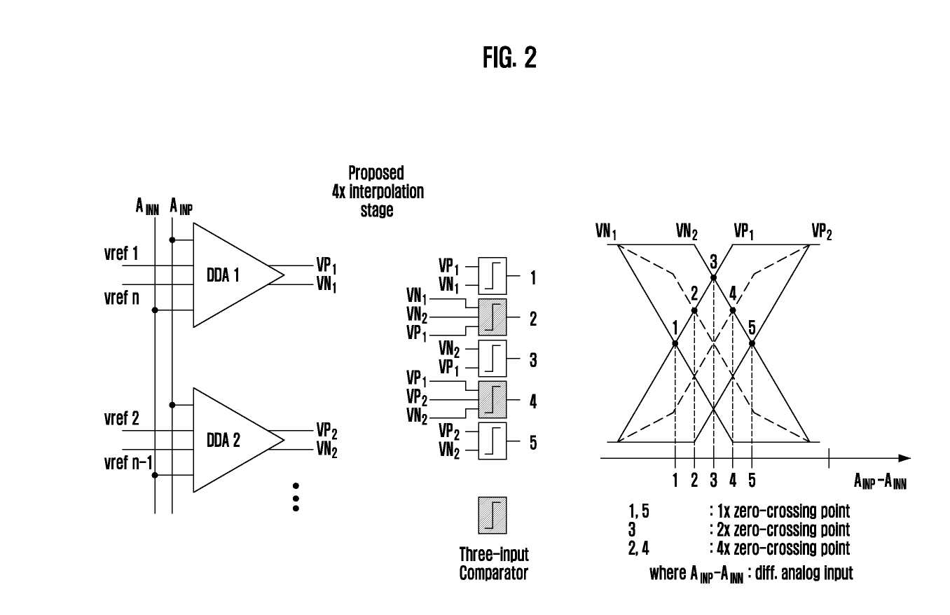

FIG. 2 is a block diagram of a flash ADC using an interpolation technology in accordance with an embodiment of the present invention. Herein, an ADC having a 6-bit resolution through a 4X interpolation circuit is exemplarily described.

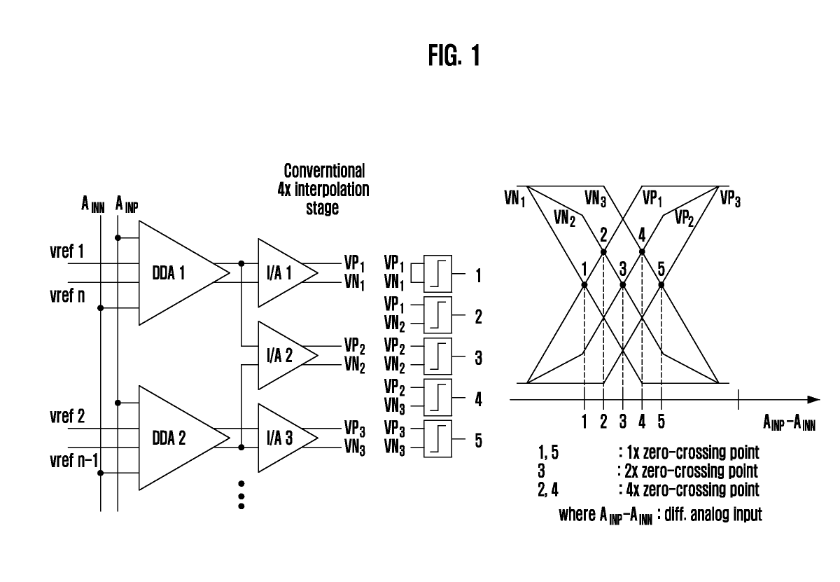

Referring to FIG. 2, the ADC includes 17 differential difference amplifiers DDA1 to DDA17 and 63 comparators 1 to 63 in order to obtain a 6-bit digital code. The 31 interpolation circuits I/A1 to I/A31 that has been used in the conventional ADC of FIG. 1 are not used in the ADC of FIG. 2.

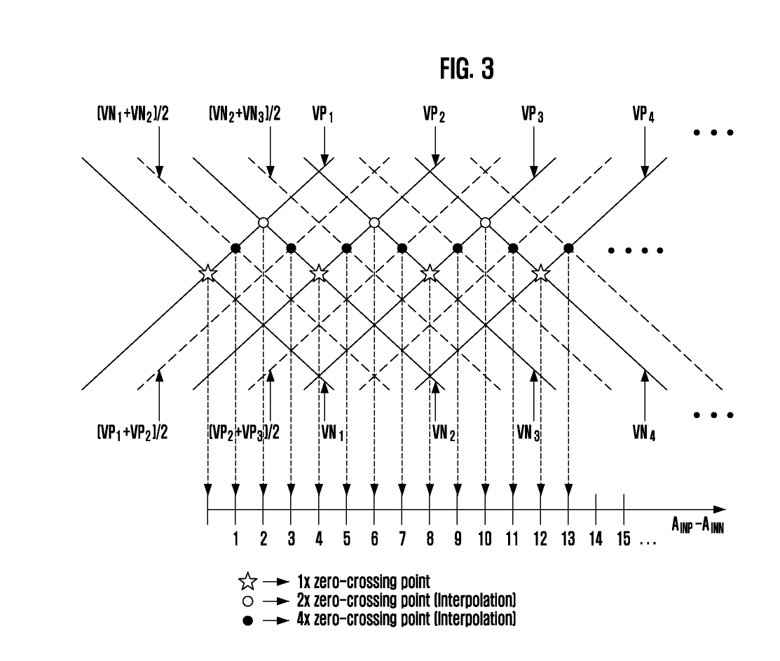

FIG. 3 is a conceptual diagram for explaining zero-crossing points using the interpolation technology in accordance with an embodiment of the present invention. Specifically, FIG. 3 shows 63 zero-crossing points required for the circuit design of the ADC that outputs the 6-bit digital code.

A case where the 4X interpolation process is achieved by performing two times the 2X interpolation process will be described below. The second zero-crossing point indicated by a white circle symbol is made from a first positive signal VP1 and a second negative signal VN2 using an amplifier of an interpolation circuit. The fourth zero-crossing point indicated by a star symbol is made using a second positive signal VP2 and a second negative signal VN2 in the same manner. If the 2X interpolation operations are separately performed two times, the third zero-crossing point indicated by a black circle symbol is made by interpolating the second zero-crossing point indicated by the white circle symbol and the forth zero-crossing point indicated by the star symbol once more. In this way, the 4X interpolation operation can be carried out.

Unlike the conventional method in which the same effect as the 4X interpolation operation is obtained by performing two times the 2X interpolation operations, the third zero-crossing point indicated by the black circle symbol is obtained by interpolating an intermediate signal (VN-1-VN2) with the second positive signal VP2 once more, where the intermediate signal is given by subtracting the second negative signal VN2 from the first negative signal VN1. A comparator for performing the above-described operation within the ADC in accordance with an embodiment of the present invention will be described below.

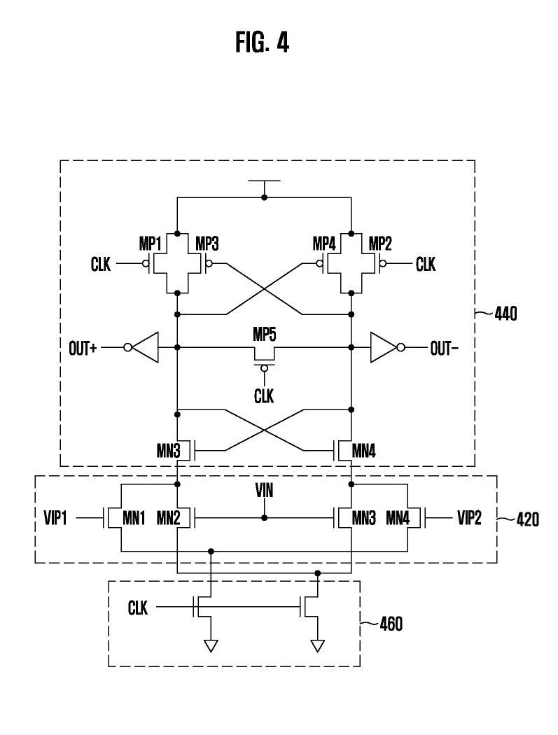

FIG. 4 is a circuit diagram of a comparator for the 4X interpolation technology in the ADC of FIG. 2 in accordance with an embodiment of the present invention.

Referring to FIG. 4, the comparator includes an input unit (MN1 to MN4) 420, a latch unit 440 (MP1 to MP4, MN5 to MN) including a reset transistor MP5, and a bias unit (MN7 to MN8) 460. The input unit 440 includes four NMOS transistors MN1 to MN4. Although the input unit 440 can receive four different signals, the input unit 440 in accordance with the embodiment of the present invention is designed to receive three input signals by connecting inputs MN2 and MN3 of the two NMOS transistors. The reset transistor MP5, the latch unit 440, and the bias unit 460 receive a clock signal CLK through their gates.

When the two NMOS transistors of the input unit 420 are configured to receive a common input value VIN by connecting their inputs MN1 and MN3, and the first and second input values VIP1 and VIP2 are input through other two NMOS transistors MN1 and MN2, the following Equations. 1 and 2 are obtained.

VIP1−VIN=VIN−VIP2 Eq. 1

VIP1+VIP2=2*VIN

(VIP1+VIP2)/2=VIN Eq. 2

That is, the comparator can make zero-crossing points through Eq. 2 according to the 4X interpolation technology. Therefore, in the ADC in accordance with the embodiment of the present invention, the comparator can achieve the above operation without separate interpolation circuits.

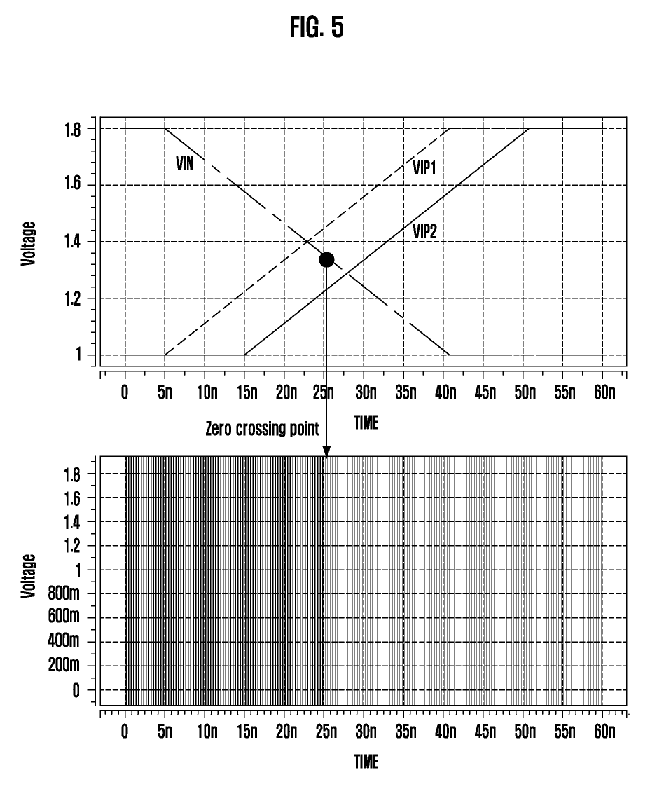

FIG. 5 is a waveform diagram for explaining the simulation result of the operation of the comparator illustrated in FIG. 4. It can be seen from the waveform diagram of FIG. 5 that the comparator operates at a crossing point between the common input value VIN and the intermediate signal of the first and second input values VIP1 and VIP2.

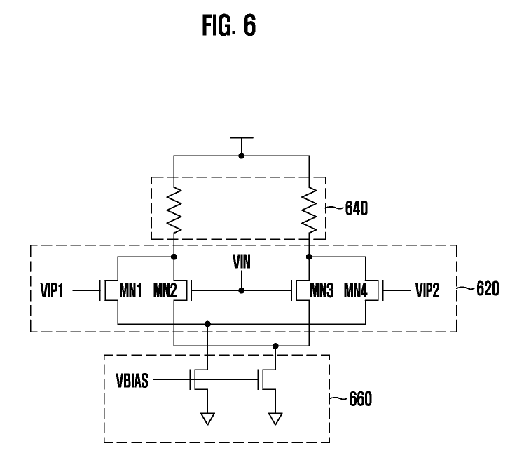

FIG. 6 is a circuit diagram of a comparator for the 4X interpolation technology in the ADC of FIG. 2 in accordance with another embodiment of the present invention.

Referring to FIG. 6, the comparator can be simply designed such that it includes a resistor unit 640, an input unit 620, and a bias unit 660, with the latch unit being removed. In this case, three input signals are received by commonly connecting two inputs among four MOS transistors of the input unit 620, thereby obtaining the same effect as the above-described comparator.

In order for the high-speed ADC requiring low power consumption and small circuit area, there is proposed a structure that can perform the 4X interpolation at a time. In order for implementing the 4X interpolation technology in accordance with the present invention, the ADC having a resolution corresponding to an N-bit digital signal includes (2N/4)+1 reference voltage resistors, (2N/4)+1 differential difference amplifiers, and 2N−1 comparators. Thus, the power consumption and the circuit area decrease by the reduced numbers of the reference voltage resistors, the differential difference amplifiers, and the interpolation circuits. In addition, since the reduction of the hardware complexity means the reduction of parasitic components of internal circuits, an operating speed of an entire circuit increases. The structure proposed in the present invention can reduce the power consumption and the circuit area of the flash ADC by 63% compared with the conventional structure.

The present application contains subject matter related to Korean Patent Application No. 2007-0128820, filed in the Korean Intellectual Property Office on Dec. 12, 2007, the entire contents of which is incorporated herein by reference.

While the present invention has been described with respect to certain preferred embodiments, it will be apparent to those skilled in the art that various changes and modifications may be made without departing from the scope of the invention as defined in the following claims.

What is claimed is:

1. An analog-to-digital converter, comprising:
a resistor string for generating a plurality of reference voltages;
a plurality of differential difference amplifiers for detecting zero-crossing points according to interpolation by using the plurality of reference voltages and input signals; and
a plurality of comparators for receiving outputs of the plurality of differential difference amplifiers, detecting zero-crossing points according to 4X interpolation, and generating a digital code corresponding to the input signals.

2. The analog-to-digital converter of claim 1, wherein each of the comparators comprises:
a preamplifier for detecting the zero-crossing points according to the 4X interpolation with respect to three input signals; and
a latch for latching outputs of the preamplifier.

3. The analog-to-digital converter of claim 2, wherein each of the comparator comprises:
a MOS transistor for removing kickback noise; and
a bias unit serving as a current source.

4. The analog-to-digital converter of claim 2, wherein the preamplifier has an amplifier structure that receives an input value through gates of four MOS transistors, two of the four MOS transistors receiving a single shared input value.

5. The analog-to-digital converter of claim 1, wherein each of the comparators comprises:
a preamplifier for detecting the zero-crossing points according to the 4X interpolation with respect to three input signals;
a resistor connected between a driving source and the preamplifier; and
a bias unit serving as a current source.

6. The analog-to-digital converter of claim 5, wherein the preamplifier has an amplifier structure that receives an input value through gates of four MOS transistors, two of the four MOS transistors receiving a single shared input value.

7. An analog-to-digital converter, comprising:
(2N/4)+1 reference voltage resistors (where N is a natural number) for generating a plurality of reference voltages;
(2N/4)+1 differential difference amplifiers for detecting zero-crossing points according to interpolation by using the plurality of reference voltages generated from the (2N/4)+1 reference voltage resistors and input signals; and
2N−1 comparators for detecting zero-crossing points according to 4X interpolation through outputs of the (2N/4)+1 differential difference amplifiers, whereby the analog-to-digital converter has a resolution corresponding to an N-bit digital signal.

8. The analog-to-digital converter of claim 7, wherein each of the comparators comprises:
a preamplifier for detecting the zero-crossing points according to the 4X interpolation with respect to three input signals; and
a latch for latching outputs of the preamplifier.

9. The analog-to-digital converter of claim 8, wherein each of the comparator comprises:
a MOS transistor for removing kickback noise; and
a bias unit serving as a current source.

10. The analog-to-digital converter of claim 8, wherein the preamplifier has an amplifier structure that receives an input value through gates of four MOS transistors, two of the four MOS transistors receiving a single shared input value.

11. The analog-to-digital converter of claim 7, wherein each of the comparators comprises:
a preamplifier for detecting the zero-crossing points according to the 4X interpolation with respect to three input signals;
a resistor connected between a driving source and the preamplifier; and
a bias unit serving as a current source.

12. The analog-to-digital converter of claim 11, wherein the preamplifier has an amplifier structure that receives an input value through gates of four MOS transistors, two of the four MOS transistors receiving a single shared input value.
